(19) United States
(12) Patent Application Publication
(10) Pub. No.: US 2024/0194728 A1
(43) Pub. Date: Jun. 13, 2024

(54) DISPLAY AND DRIVING METHOD FOR THE SAME

(71) Applicant: Kookmin University Industry Academy Cooperation Foundation, Seoul (KR)

(72) Inventor: YOUNG RAG DO, Seoul (KR)

(21) Appl. No.: 18/536,804

(22) Filed: Dec. 12, 2023

(30) Foreign Application Priority Data
Dec. 13, 2022 (KR) 10-2022-0173463

(51) Int. Cl. H01L 27/15; G09G 3/32; H01L 23/552; H01L 33/40

(52) U.S. Cl. CPC H01L 27/156; G09G 3/32; H01L 23/552; H01L 33/405

(57) ABSTRACT

A pixel structure and driving method of an ultra-thin device display with alignment and driving electrode switching functions.

### CROSS-REFERENCE TO RELATED APPLICATION

This application claims priority to and the benefit of Korean Patent Application No. 10-2022-0173463, filed on Dec. 13, 2022, the disclosure of which is incorporated herein by reference in its entirety.

### 1. TECHNICAL FIELD

The present invention relates to a pixel structure technique for displays, and more specifically to a pixel structure technique in which a switching function is implemented to enable function switching to alignment and driving electrodes in a display equipped with ultra-thin fin LED devices.

### 2. RELATED ART

Nano-LED is a light-emitting device with a nano-scale LED, and micro-LED is a light-emitting device with a micro-scale LED. These micro-LEDs and nano-LEDs (hereinafter, referred to as “micro-nano LEDs”) are self-luminous devices that can implement excellent color and high efficiency, are environmentally friendly and have a long lifespan. Accordingly, micro-nano LEDs are being used as a core material for displays. As a result, research and development are in progress to apply micro-LED displays or nano-LED displays equipped with micro-nano LEDs to various displays such as smartphones and TVs. Additionally, in order to commercialize micro-LED or nano-LED displays, research is being actively conducted on new structures and new patterning manufacturing processes.

Recently, large displays for TVs larger than 100 inches using red, green and blue micro-LEDs have been commercialized. In the future, TVs that implement full color through blue subpixels implemented by using blue micro-LEDs or nano-LEDs, and red and green subpixels implemented by emitting quantum dots through blue LEDs will be commercialized. Moreover, red, green and blue nano-LED display TVs are also scheduled to be commercialized.

Micro-LED displays have the advantages of high-performance characteristics, very long theoretical lifespan and high efficiency. However, when developing such a micro-LED display into a display with 8K resolution, a red micro-LED, a green micro-LED and a blue micro-LED must be corresponded one-to-one for each of approximately 100 million subpixels. Accordingly, the current pick place technology for manufacturing micro-LED displays has problems such as high unit cost, high process defect rate and low productivity, thereby making it difficult to manufacture truly high-resolution commercial displays ranging from smartphones to TVs. In particular, the situation is that it is more difficult to individually place nano-LEDs in subpixels by using the pick and place technology such as micro-LEDs.

In order to overcome these difficulties, Korean Registered Patent Publication No. 10-1436123 was proposed. This related art discloses a display in which a solution mixed with nanorod-type LEDs is dropped onto a subpixel, and then, an electric field is formed between two alignment electrodes to magnetically align the nanorod-type LED devices on the electrodes, thereby implementing a subpixel. However, in this display, the electrodes that apply current to the n-type semiconductor layer are present by being spaced horizontally from the p-type semiconductor layer of the nanorod-type LED device, and thus, when producing subpixels, there is a problem in that the horizontal and vertical electrode arrays for addressing are not easy. In addition, the nanorod-type LED used in the corresponding display is not efficient because the area from which light is extracted is small, and thus, there is a problem in that a large number of LEDs must be mounted to achieve the desired efficiency, and there is a problem with the high possibility of inevitable defects occurring in the manufacturing process of the nanorod-type LED itself.

Hereinafter, the inevitable defects of the nanorod-type LED itself will be explained in detail. Nanorod-type LED devices are known to be manufactured by using the top-down method by mixing the nano-patterning process and dry etching/wet etching on an LED wafer, or the method of growing directly on a substrate by the bottom-up method is known. In these nanorod-type LEDs, the long axis of the LED coincides with the stacking direction, that is, the stacking direction of each layer in the p-GaN/InGaN multiple quantum well (MQW)/n-GaN stacked structure. Accordingly, in the case of nanorod-type LEDs, since the emission area is small, surface defects have a relatively large effect on reducing efficiency, and since it is difficult to optimize the electron-hole recombination speed, there is a problem in that the light-emitting efficiency is significantly lower than the original efficiency of the wafer.

In order to solve these problems with nanorod-type LEDs, a micro-nano LED device with a new ultra-thin shape such as Korean Registered Patent Publication No. 10-2345917 (hereinafter, also referred to as an “ultra-thin device” or an “ultra-thin fin LED device”) has been proposed. In the case of these ultra-thin devices, electrode placement for addressing can be more easily implemented when manufacturing subpixels, and ultra-small devices in the micro or nanoscale can be easily arranged by using electric fields. In addition, the ultra-thin device has a large light-emitting area, the reduction in efficiency due to surface defects is minimized, and the electron-hole recombination speed can be optimized.

When implementing pixels of a display using such ultra-thin devices, an alignment electrode is needed to align the ultra-thin devices in the pixel, and a driving electrode is needed to operate the aligned ultra-thin devices in the pixel. In this case, the alignment electrode is located at the bottom to form a horizontal electric field, thereby aligning the ultra-thin devices located at the top according to the horizontal electric field. In addition, the driving electrode is located below and above the aligned ultra-thin devices to apply the current necessary for light emission of the ultra-thin devices in the vertical direction.

In the pixels of displays using such ultra-thin devices, when the alignment and driving electrodes are implemented separately, there is a problem in that the pixel structure becomes complicated and manufacturing costs increase. In order to solve this problem, a new electrode structure that can be used for the alignment and driving of ultra-thin devices is needed.

However, the above-described content merely provides background information on the present invention and does not correspond to previously disclosed technology.

### RELATED ART DOCUMENTS

(Patent Document 1) KR 10-1436123 B
(Patent Document 2) KR 10-2345917 B

### SUMMARY

In order to solve the problems of the related art as described above, an aspect of the present invention is to provide an electrode structure technique that can be used for aligning and driving the corresponding LED devices in the pixel structure of a display using ultra-thin fin LED devices.

That is, the present invention is directed to providing a pixel structure technique which implements a switching function that is capable of switching functions between alignment and driving electrodes in the pixel structure of a display using ultra-thin fin LED devices.

However, the problems to be solved by the present invention are not limited to the problems mentioned above, and other problems that are not mentioned will be clearly understood by those skilled in the art from the description below.

The present invention has been researched under support of National Research and Development Project, and specific information of National Research and Development Project is as follow:
[Project Series Number] 1415174040
[Project Number] 20016290
[Government Department Name] Ministry of Trade, Industry and Energy
[Project Management Authority Name] Korea Evaluation Institute of Industrial Technology
[Research Program Name] Electronic Components Industry Technology Development-Super Large Micro-LED Modular Display
[Research Project Name] Development of sub-micron blue light-emitting source technology for modular display
[Project Execution Organization Name] Kookmin University Industry Academic Cooperation Foundation
[Period of Research] Apr. 1, 2021 to Dec. 31, 2024
[Project Series Number] 1711130702
[Project Number] 2021R1A2C2009521
[Government Department Name] Ministry of Science and ICT
[Project Management Authority Name] Korea Evaluation Institute of Industrial Technology
[Research Program Name] Middle-level Researcher Support Project
[Research Project Name] Development of dot-LED material and display source/application technology
[Project Execution Organization Name] Kookmin University Industry Academic Cooperation Foundation
[Period of Research] Mar. 1, 2023 to Feb. 28, 2026

In order to solve the above-described problems, the display according to an exemplary embodiment of the present invention includes a lower electrode comprising a plurality of electrodes that are spaced apart in the horizontal direction at a predetermined interval; ultra-thin fin LED devices as devices in which the length is greater than the thickness and a first conductive semiconductor layer, a photoactive layer and a second conductive semiconductor layer are stacked in the thickness direction, and at least two thereof are provided for each of a plurality of sub-pixel sites formed on the lower electrode; an upper electrode disposed to contact the top of the ultra-thin fin LED devices; and a switch with one end connected to the first electrode and the other end connected to the second electrode for the first and second electrodes that are adjacent to the lower electrode in each subpixel space, wherein in the on state of the switch, a driving function for the ultra-thin fin LED devices is performed.

The driving function and an alignment function for the ultra-thin fin LED devices may switched depending on the on/off of the switch, and when the alignment function is performed, the switch may be turned off.

An alignment function for the ultra-thin fin LED devices may be performed in the off state of the switch, and the alignment function may be performed during a manufacturing process.

During the alignment function, a high voltage may be applied to the first electrode and a low voltage is applied to the second electrode.

During the driving function, a high voltage may be applied to the upper electrode and a low voltage is applied to the lower electrode.

During the driving function, a low voltage may be alternately applied to the first and second electrodes.

The lower electrode may be provided in the form of a plate and include a reflective material on a surface that reflects the light emitted from the ultra-thin fin LED devices in each subpixel space to an upper portion which is the front surface.

The lower electrode may include a shielding material that blocks an electric field induced from a transistor and a signal line that are disposed on the lower side in each subpixel space.

The lower electrode may be provided in the form of a plate, include a reflective material on a surface that reflects the light emitted from the ultra-thin fin LED devices in each subpixel space to an upper portion, which is the front surface, and include a shielding material that blocks an electric field induced from a transistor and a signal line that are disposed on the lower side.

Each thickness of the first and second electrodes in the horizontal direction is greater than a separation interval in the horizontal direction between the first and second electrodes.

A separation interval in the horizontal direction between the second electrode located in the first subpixel space and a third electrode located in the second subpixel space but adjacent to the second electrode may be smaller than each thickness in the horizontal direction of the first and second electrodes.

The method for driving a display according to an exemplary embodiment of the present invention is a method for driving a display including the above-described structure, and includes a driving step of performing the driving function when the switch is turned on.

The method according to an exemplary embodiment of the present invention may further include the step of switching the driving function and an alignment function for the ultra-thin fin LED devices according to the on/off of the switch, wherein when the alignment function is performed, the switch is turned off.

During the alignment function, a high voltage may be applied to the first electrode and a low voltage is applied to the second electrode.

The driving step may include the step of applying a high voltage to the upper electrode and applying a low voltage to the lower electrode.

The driving step may include the step of applying a low voltage alternately to the first and second electrodes.

The present invention configured as described above has the advantage of providing an electrode structure technique that can be used for aligning and driving the corresponding LED devices in the pixel structure of a display using ultra-thin fin LED devices.

That is, the present invention has the advantage of efficiently performing the alignment and driving functions by implementing a switching function that allows switching between alignment and driving electrodes in the pixel structure of a display using ultra-thin fin LED devices.

In addition, the present invention has the advantage of significantly improving the lifespan of the ultra-thin fin LED device affected by the voltage of the adjacent electrodes, by applying a low voltage alternately to the first and second electrodes among the adjacent electrodes of the lower electrode when performing the driving function.

In addition, the present invention has the advantage of contributing to improving image quality while implementing reflection and shielding functions at low cost through the lower electrode.

The effects that can be obtained from the present invention are not limited to the effects mentioned above, and other effects that are not mentioned will be clearly understood by those skilled in the art from the description below.

### BRIEF DESCRIPTION OF THE DRAWINGS

FIG. 1 shows a plan mimetic diagram of a display 1000 according to an exemplary embodiment of the present invention.

FIG. 2 shows a cross-sectional mimetic diagram along the X-X′ boundary line in FIG. 1.

FIG. 3 shows a mimetic diagram of the operation of a switch 700 for aligning a micro-nano LED device 100 in any one pixel of the display 1000 according to an exemplary embodiment of the present invention.

FIG. 4 shows a mimetic diagram of the operation of a switch 700 for driving a micro-nano LED device 100 in any one pixel of the display 1000 according to an exemplary embodiment of the present invention.

FIG. 5 shows a mimetic diagram of a micro-nano LED device 100 included in an exemplary embodiment of the present invention.

FIG. 6 shows a mimetic diagram of a horizontally arranged rod-type LED device 100′, which is the related art, respectively.

FIG. 7 shows a flowchart of the driving method according to an exemplary embodiment of the present invention.

### DETAILED DESCRIPTION OF EXEMPLARY EMBODIMENTS

The above-described aspects and means of the present invention and the effects associated therewith will become more apparent through the following detailed description in conjunction with the accompanying drawings. Accordingly, those skilled in the art to which the present invention pertains can readily implement the technical spirit of the present invention. In addition, when it is determined that the detailed descriptions of related well-known functions unnecessarily obscure the gist of the present invention during the description of the present invention, the detailed descriptions thereof will be omitted.

Terms used herein are for the purpose of describing exemplary embodiments only and are not intended to limit the present invention. In the present specification, the singular forms are intended to include the plural forms as well in some cases, unless the context clearly indicates otherwise. In the present specification, terms such as “comprises,” “comprising,” “includes,” “including,” “has” and/or “having” do not preclude the presence or addition of one or more other components other than the components mentioned.

In the present specification, terms such as “or,”, “at least one” and the like may represent one of the words listed together or may represent a combination of two or more. For example, “A or B” and “at least one of A and B” may include only one of A or B, and may include both A and B.

In the present specification, descriptions following “for example” may not exactly match the information presented, such as cited characteristics, variables or values, and the exemplary embodiments of the present invention according to various examples of the present invention should not be limited by effects such as modifications including the limits of tolerances, measurement errors and measurement accuracy, and other commonly known factors.

In the present specification, when it is described that one component is “connected” or “joined” to another component, it should be understood that the one component may be directly connected or joined to another component but an additional component may be present therebetween. However, when one component is described as being “directly connected” or “directly coupled” to another component, it should be understood that the additional component may be absent between the one component and another component.

In the present specification, when one component is described as being “on” or “facing” another component, it should be understood that the one component may be directly in contact with or connected to another component, but additional component may be present between the one component and another component. However, when one component is described as being “directly on” or “in direct contact with” another component, it should be understood that there is no additional component between the one component and another component. Other expressions describing the relationship between components, such as “between ^{˜},” “directly between ˜” and the like should be interpreted in the same way.

In the present specification, terms such as “first” and “second” may be used to describe various components, but the components should not be limited by the above terms. In addition, the above terms should not be interpreted as limiting the order of each component but may be used for the purpose of distinguishing one component from another. For example, a “first component” could be termed a “second component”, and similarly, a “second component” could also be termed a “first component.”

Unless defined otherwise, all terms used herein may be used in a sense commonly understood by those skilled in the art to which the present invention pertains. In addition, it should be understood that terms, such as those defined in commonly used dictionaries, will not be interpreted in an idealized or overly formal sense unless expressly so defined herein.

Hereinafter, a preferred exemplary embodiment according to the present invention will be described in detail with reference to the attached drawings.

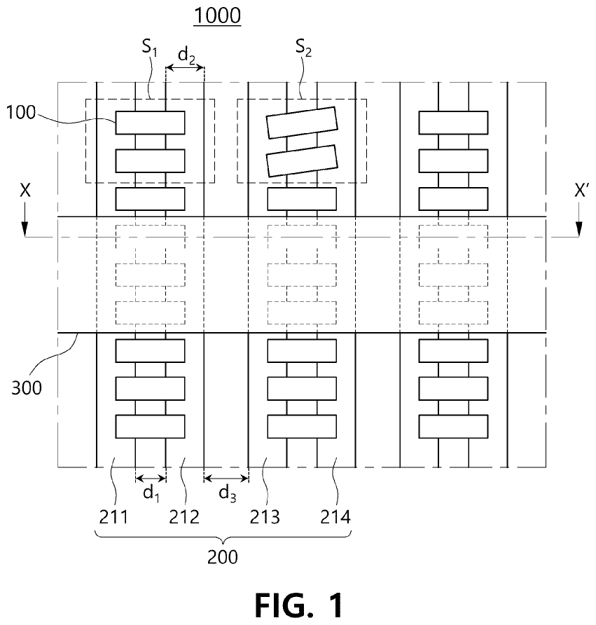

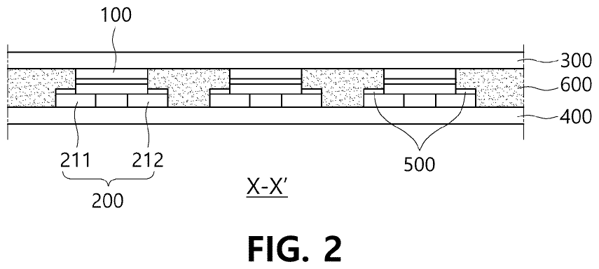

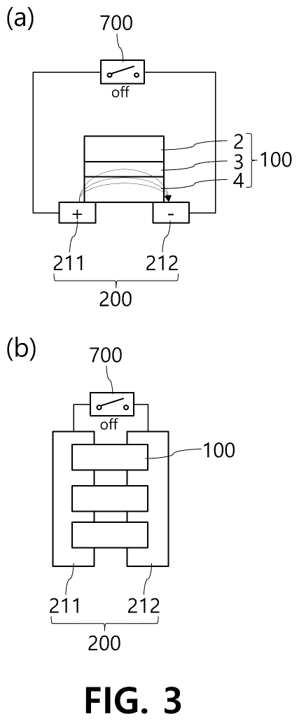

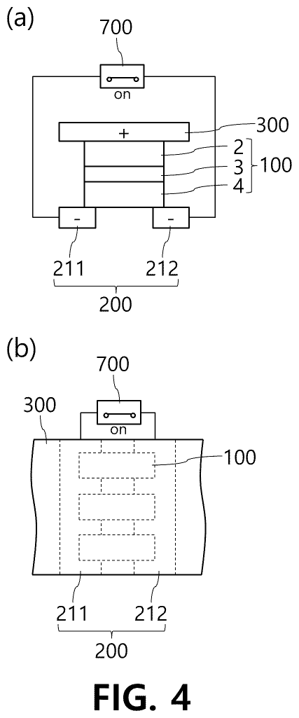

FIG. 1 shows a plan mimetic diagram of a display 1000 according to an exemplary embodiment of the present invention, and FIG. 2 shows a cross-sectional mimetic diagram along the X-X′ boundary line in FIG. 1. In addition, FIG. 3 shows a mimetic diagram of the operation of a switch 700 for aligning a micro-nano LED device 100 in any one pixel of the display 1000 according to an exemplary embodiment of the present invention, and FIG. 4 shows a mimetic diagram of the operation of a switch 700 for driving a micro-nano LED device 100 in any one pixel of the display 1000 according to an exemplary embodiment of the present invention.

The display 1000 according to an exemplary embodiment of the present invention is a full-color LED display device which is implemented to include ultra-thin micro-nano LED devices in each pixel space (sub-pixel sites) S1, S2. These ultra-thin micro-nano LED devices may also be referred to as “ultra-thin devices” or “ultra-thin LED devices.”

Referring to FIGS. 1 to 4, the display 1000 may include a lower electrode 200 including a plurality of electrodes 211, 212, 213, 214 that are spaced apart in the horizontal direction at a predetermined interval, micro-nano LED devices 100 which are ultra-thin LED devices that emit light by including at least two devices in each of a plurality of subpixel spaces S1, S2 that are formed on the lower electrode 200, an upper electrode 300 which is disposed to contact the top of the electrode 100, and a switch 700 with one end and the other end respectively connected to the electrodes 211, 212 that are adjacent to the lower electrode 200, respectively. Such a lower electrode 200, micro-nano LED devices 100 and upper electrode 300 may be implemented on a substrate 400.

First of all, the electrode structure for magnetic alignment and light emission of micro-nano LED devices will be described.

The present display 1000 includes an upper electrode 300 and a lower electrode 200 that are disposed to be opposite to each other at the top and bottom with the micro-nano LED device 100 interposed therebetween. Since the upper electrode 300 and the lower electrode 200 are not arranged in the horizontal direction, compared to a display (hereinafter, referred to as a “conventional display”) that is implemented to magnetically align the devices through electric field induction in the related art, the electrode design is very simple and easy to implement, making it possible to solve the problems of a conventional display. That is, the conventional display has a problem of having complex electrodes in which two types of electrodes are arranged such that the electrodes of ultra-small thickness and width are disposed to have micro- or nano-unit intervals in the horizontal direction within a plane of a limited area. In addition, since the present display 1000 is easy to arrange TFTs, not only active matrix driving but also passive matrix driving (x-y matrix driving) is possible, which has the advantage of making it much easier to implement various types of displays.

The lower electrode 200 is an assembled electrode for magnetically aligning the micro-nano LED devices 100 such that the upper or lower surfaces of the micro-nano LED devices 100 in the thickness direction contact each other. At the same time, the lower electrode 200 functions as one of the driving electrodes provided to emit light from the micro-nano LED device along with the upper electrode 300, which will be described below. Certainly, even in conventional displays, ultra-small LEDs are mounted on electrodes that are spaced apart in the horizontal direction. In this case, conventional displays use the same electrodes (i.e., electrodes spaced apart in the horizontal direction) as driving electrodes to emit light from ultra-small LED devices, and accordingly, assembled electrodes and driving electrodes may be possible with only the lower electrode. On the other hand, in the present invention, the lower electrode 200 functions as an assembled electrode, but the micro-nano LED device cannot emit light with the lower electrode 200 alone, and this is different from conventional displays.

The lower electrode 200 includes a plurality of electrodes 211, 212, 213, 214 that are spaced apart in the horizontal direction at a predetermined interval. This lower electrode 200 functions as one of the driving electrodes provided to emit light from the micro-nano LED device 100. In this case, since one surface of the micro-nano LED device in the thickness direction is electrically connected to the lower electrode 200, there is little need to design a large number of lower electrodes 200 by having them spaced apart in the horizontal direction. However, in order to function as an assembled electrode for magnetic alignment of the micro-nano LED device on the lower electrode 200, it may include electrodes 211, 212, 213, 214 at the appropriately set number and intervals of lower electrodes 200 in consideration of the length of the micro-nano LED device.

Meanwhile, the interval between adjacent electrodes 211, 212 may be smaller than the length of the micro-nano LED device 100. If the interval between two adjacent electrodes is the same or wider than the length of the micro-nano LED device, the micro-nano LED device may be magnetically aligned in the form of being sandwiched between two adjacent electrodes. In this case, there is a high possibility that an electrical short circuit will occur due to contact between the side surface of the electrode and the photoactive layer exposed on the side surface of the micro-nano LED device.

There is no limitation to the specific electrode arrangement of a plurality of electrodes 211, 212, 213, 214 that are included in the lower electrode 200 as long as they are arranged to be spaced apart in the horizontal direction. For example, a plurality of electrodes 211, 212, 213, 214 may have a structure in which a plurality of electrodes 211, 212, 213, 214 are arranged side by side at a predetermined interval in one direction, but the present invention is not limited thereto.

The upper electrode 300 is an electrode designed to make electrical contact with the top of the micro-nano LED devices 100 that are mounted on the lower electrode 200, and there is no limitation on the number, arrangement and shape thereof. However, as illustrated in FIG. 1, if the lower electrodes 200 are arranged side by side in one direction, the upper electrodes 300 may be arranged perpendicular to one direction. This electrode arrangement is an electrode arrangement that has been widely used in various displays in the past, and it has the advantage of being able to use electrode arrangement and control technology in various conventional display fields as is.

Meanwhile, FIG. 1 illustrates the upper electrode 300 covering only some devices, but other parts are omitted for the ease of description. That is, unlike what is illustrated in FIG. 1, there may be an additional upper electrode 300, which is not illustrated, disposed on the top of the micro-nano LED device.

The lower electrode 200 and the upper electrode 300 may have the material, shape, width and thickness of electrodes that are used in conventional displays, and may be manufactured by using known methods, and the present invention does not specifically limit the same. For example, the electrode may be aluminum, chrome, gold, silver, copper, graphene, ITO or an alloy thereof, and may have a width of 2 to 50 μm and a thickness of 0.1 to 100 μm, but it may be changed appropriately in consideration of the size of the desired display and the like.

In particular, the alignment function is performed by using the lower electrode 200 such that the micro-nano LED device 100 is disposed between adjacent electrodes 211, 212. That is, the corresponding alignment function may be performed such that one end of the lower surface of the micro-nano LED device 100 is located on the first electrode 211 of the adjacent electrodes 211, 212, and the other end of the lower surface of the micro-nano LED device 100 is located on the second electrode 212.

Specifically, referring to FIGS. 3 and 4, the alignment function may be performed such that one end of the micro-nano LED device 100 is located on the first electrode 211 of the electrodes 211, 212 that are adjacent and spaced apart from each other, and the other end of the micro-nano LED device 100 is located on the second electrode 212. That is, according to the performance of the alignment function, it is possible to implement the alignment in which one end of a second conductive semiconductor layer 4 of the micro-nano LED device 100, which will be described below, is located on the first electrode 211, and the other end of a second conductive semiconductor layer 4 of the micro-nano LED device 100, which will be described below, is located on the second electrode 212. In this case, the upper electrode 300 is placed on one side (i.e., the upper side in FIG. 3) of a first conductive semiconductor layer 2 located on one side (i.e., the upper side in FIG. 3) of the aligned micro-nano LED device 100.

However, the present invention is not limited thereto, and the alignment may be performed such that one end of the first conductive semiconductor layer 2 of the micro-nano LED device 100, which will be described below, is located on the first electrode 211 of the adjacent electrodes 211, 212, and the other end of the second conductive semiconductor layer 2 of the micro-nano LED device 100, which will be described below, is located on the second electrode 212. In this case, the upper electrode 300 is disposed on the first conductive semiconductor layer 2 of the micro-nano LED device 100, which will be described below. In this case, the upper electrode 300 is disposed on the second conductive semiconductor layer 4 located on the upper side of the aligned micro-nano LED device 100.

In particular, the present invention further includes a switch 700 to implement a switching function that allows the alignment function and the driving function (or referred to as “light-emission driving function”) to be switched as necessary, respectively. For example, the switch 700 may include a device having a switching function to turn on/off the electrical connection at both ends according to a driving signal from a driving unit (not illustrated). For example, the switch 700 may include a MOSFET device, but the present invention is not limited thereto.

In this case, the alignment function refers to a function of magnetically aligning and disposing the micro-nano LED device 100 on the top of the adjacent electrodes 211, 212 through an electric field generated by the voltage applied to the adjacent electrodes 211, 212 of the lower electrode 200. In addition, the driving function refers to a function of driving the micro-nano LED element 100 to emit light while supplying driving power to the micro-nano LED element 100 arranged in alignment between these electrodes 200, 300 through the voltage applied to the lower electrode 200 and the upper electrode 300.

For the switching function between the alignment and driving functions, one end of the switch 700 is connected to the first electrode 211 of the adjacent electrodes 211, 212 of the lower electrode 200, and the other end of the switch 700 is connected to the second electrode 212. For example, the switch 700 may be provided to operate in each pixel space or may be provided to operate in a grouped pixel space, but the present invention is not limited thereto.

When the alignment function needs to be performed, as illustrated in FIG. 3, the switch 700 is turned off, and the connection between the adjacent electrodes 211, 212 of the lower electrode 200 is disconnected. In this state, a high voltage (e.g., + voltage) required for alignment of the micro-nano LED device 100 is applied to the first electrode 211, and a low voltage (e.g., − voltage) or ground (GND) is connected to the second electrode 212. Accordingly, an electric field is generated between the adjacent electrodes 211, 212 of the lower electrode 200 according to the voltage difference between these electrodes 211, 212 such that the micro-nano LED device 100 may be arranged in magnetic alignment on the top thereof. That is, the micro-nano LED devices 100 may be aligned by dielectrophoresis. Certainly, in this case, no voltage may be applied to the upper electrode 300.

On the other hand, when the driving function needs to be performed, as illustrated in FIG. 4, the switch 700 is turned on, and the adjacent electrodes 211, 212 of the lower electrode 200 are electrically connected. Accordingly, adjacent electrodes 211, 212 of the lower electrode 200 may have the same potential with each other. In this state, a high voltage (e.g., + voltage) required for driving the micro-nano LED device 100 is applied to the upper electrode 300, and a low voltage (e.g., + voltage) or ground (GND) is connected to the adjacent electrodes 211, 212 of the lower electrode 200. Accordingly, power according to the high and low voltages is supplied to the micro-nano LED device 100 disposed between the lower and upper electrodes 200, 300 such that the micro-nano LED device 100 may be driven to emit light.

According to the connection of the switch 700, the present invention may provide an electrode structure that can be used for aligning and driving the corresponding LED device 100 in the pixel structure of the display 1000 using the micro-nano LED device 100. That is, the lower electrode 200 may be used as an electrode to provide an alignment function for the micro-nano LED device 100 when the switch 700 is in an off state. In addition, the lower electrode 200 and the upper electrode 300 may be used as electrodes for a driving function for the aligned micro-nano LED devices 100 when the switch 700 is turned on. As a result, the present invention has the advantage of being able to perform the alignment and driving functions and switching between these functions more easily, quickly and efficiently.

Meanwhile, when the driving function is performed, a low voltage may be alternately applied to the first electrode 211 and the second electrode 212 among the adjacent electrodes 211, 212 of the lower electrode 200. For example, during a first time, a low voltage is applied only to the first electrode 211, and no low voltage is applied to the second electrode 212, and afterwards, during a second time, a low voltage is applied only to the second electrode 212, and a low voltage may not be applied to the first electrode 211, and these first and second times may be repeated. In this case, as a low voltage is alternately applied to the adjacent electrodes 211, 212 of the lower electrode 200, it has the advantage of significantly improving the lifespan of the micro-nano LED device 100 affected by the voltage of the corresponding adjacent electrodes 211, 212.

Additionally, although a driving unit (not illustrated) provided with a circuit for driving the switch 700 is not separately illustrated, this driving unit may include a typical circuit for driving a switch device. That is, when the driving unit receives a first control signal for the alignment function from a control unit (not illustrated) of the display 1000, it may transmit a signal for driving the switch 700 to be turned off to the switch 700 according to the first control signal. In addition, when the driving unit receives a second control signal for the driving function from the control unit of the display 1000, it may transmit a signal for driving the switch 700 to be turned off according to the second control signal.

However, the operation time of the drive function generally takes longer than that of the alignment function. Accordingly, the switch 700 and the driving unit may be implemented to reduce power usage by reflecting this point. That is, if a separate driving signal from the driving unit is not provided to the switch 700 or a lower voltage is applied, the switch 700 is turned on by default, but may be implemented to be turned off only when a specific driving signal with a higher voltage is provided to the switch 700 from the driving unit. In this case, when the driving unit receives a first control signal for the alignment function from the control unit, it may transmit a high voltage signal to the switch 700 to drive to turn off the switch 700 according to the first control signal. In addition, when the driving unit receives a second control signal for the driving function from the control unit of the display 1000, it does not provide a separate driving signal to the switch 700 or transmits a low voltage signal to the switch 700 so as to turn off the switch 700.

For example, when the switch 700 is implemented by including a MOSFET device, one end of the above-described switch 700 may be any one of a source or drain electrode of the MOSEFET, and the other end of the above-described switch 700 may be the other one of a source or a drain electrode of the MOSEFET. In this case, the driving signal of the driving unit may be applied to a gate electrode of the MOSEFET.

The above-described alignment function may be performed during the manufacturing process of the display 1000, but the present invention is not limited thereto, and it may be additionally performed if necessary while the driving function is performed after the manufacturing process of the display 1000.

Meanwhile, in order to increase the light-emitting efficiency, a reflection function is required to reflect the light generated from each pixel such that it is emitted to the front surface. Additionally, electric fields are generated due to peripheral transistors (TFTs) in the pixel space and signal lines connected to the TFTs. Since these electric fields have a negative effect on the light-emitting efficiency, a crisis shielding function is necessary to reduce the negative effects of these electric fields.

However, when these reflective electrodes and shielding structures are additionally provided, there is a problem in that the manufacturing process becomes complicated and the manufacturing cost increases. In order to solve this problem, in the present display 1000, the lower electrode 200 may be implemented to have both of the reflection function and the shielding function.

That is, the lower electrode 200 is provided in the form of a plate and includes a reflective material on the surface thereof to reflect the light emitted from the plurality of micro-nano LED devices 100 in each subpixel space S1, S2 upward (front). In this case, the reflective material may include any material that has the property of reflecting light. For example, the reflective material may include Ag, Au, Al, Cr or Ni, or an alloy thereof, but the present invention is not limited thereto. Additionally, the lower electrode 200 includes a plurality of transistors (TFTs) disposed below and a shielding material that blocks electric fields induced from signal lines connected to the TFTs. In this case, the shielding material may include any material that has the property of blocking light. Accordingly, the present invention has the advantage of being able to implement the reflection and shielding functions at low cost through the lower electrode 200 and at the same time contribute to improving image quality.

In this case, in order to increase the efficiency of the reflection function and shielding function, it is necessary to expand the area of the lower electrode 200 in the horizontal direction. To this end, referring to FIG. 1, in any one pixel space S1, the thickness d2 of each of the adjacent electrodes 211, 212 of the lower electrode 200 in the horizontal direction may be preferably greater than a separation interval d1 in the horizontal direction between the corresponding electrodes 211, 212.

In addition, since the area between the subpixel spaces S1, S2 has little influence on the efficiency of the reflection function and shielding function, in the lower electrode 200, the horizontal interval d3 between the adjacent electrodes 212 and 213 located in different subpixel spaces S1, S2 may be greater than d1. That is, d3 is the separation interval in the horizontal direction between the second electrode 212 located in the first subpixel space S1 and the third electrode 213 located in the second subpixel space S2 adjacent to the second electrode 212.

Additionally, in order to maximize the efficiency of the reflection function and shielding function, it may be desirable for d2 to be greater than d1 and d3, unlike as illustrated in FIG. 1.

In this case, a technique (hereinafter, referred to as a “prevention technique”) for preventing the micro-nano LED device 100 from being placed between the second electrode 212 and the third electrode 213 may be required. In other words, the prevention technique corresponds to a technique for preventing one side of the micro-nano LED device 100 from being located on the second electrode 212 and the other side of the micro-nano LED device 100 from being located on the third electrode 213.

In order to implement this prevention technique, when the above-described alignment function is performed, the same voltages of the high voltage and low voltage may be preferably applied to the second electrode 212 and the third electrode 213 that are located adjacent to each other in different subpixel spaces S1, S2.

For example, when the above-described alignment function is performed, a high voltage may be applied to the first electrode 211, and a low voltage may be applied to the second electrode 212 in a first subpixel space S1. In this case, in a second subpixel space S2, the same low voltage as that of the second electrode 212 may be applied to the third electrode 211 adjacent to the second electrode 212, and a high voltage may be applied to the fourth electrode 214.

Alternatively, when the above-described alignment function is performed, a low voltage may be applied to the first electrode 211, and a high voltage may be applied to the second electrode 212 in the first subpixel space S1. In this case, in the second subpixel space S2, the same high voltage as that of the second electrode 212 may be applied to the third electrode 211 adjacent to the second electrode 212, and a low voltage may be applied to the fourth electrode 214.

Certainly, the above-described prevention technique may also be applied when d2 is smaller than d1 or d3.

Next, the micro-nano LED device 100 disposed between the lower electrode 200 and the upper electrode 300 described above will be described.

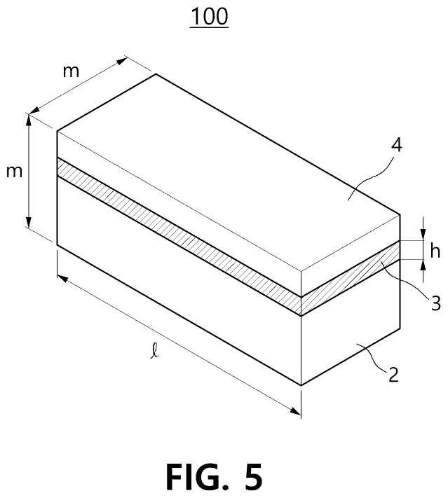

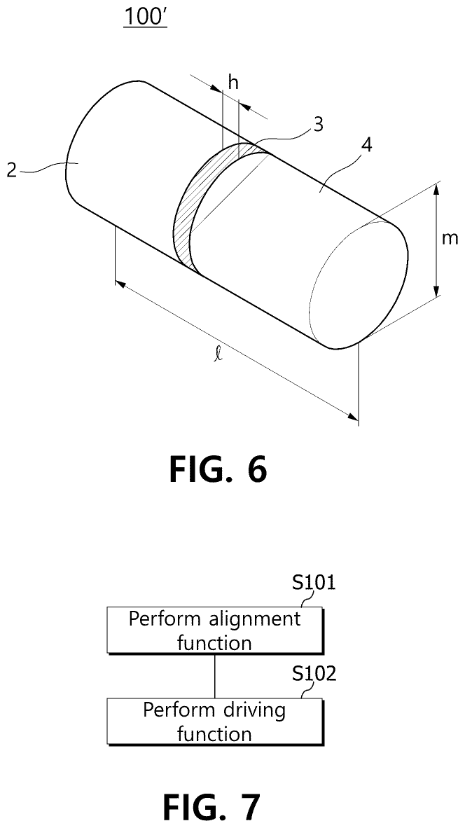

FIG. 5 shows a mimetic diagram of a micro-nano LED device 100 included in an exemplary embodiment of the present invention, and FIG. 6 shows a mimetic diagram of a horizontally arranged rod-type LED device 100′, which is the related art, respectively.

That is, FIG. 5 shows a mimetic diagram of a micro-nano LED device 100 included in an exemplary embodiment of the present invention in which the first conductive semiconductor layer 2, the photoactive layer 3 and the second conductive semiconductor layer 4 are stacked in the thickness direction. On the other hand, FIG. 6 shows a mimetic diagram of a horizontally arranged rod-type LED device 100′ in which the first conductive semiconductor layer 2, the photoactive layer 3 and the second conductive semiconductor layer 4 are stacked in the longitudinal direction.

The micro-nano LED device 100, which is an ultra-thin fin LED device, is arranged to be included in at least two in a plurality of subpixels S1, S2 on the lower electrode 200, and through this, even if a defective device is included among the micro-nano LED elements arranged in each subpixel, since all subpixels can emit a predetermined amount of light, the occurrence of defective pixels in the display may be minimized or prevented.

Meanwhile, as illustrated in FIGS. 1 and 2, the micro-nano LED device 100 maybe disposed such that one surface in the thickness direction where each layer is stacked on the two adjacent electrodes 211, 212 of the lower electrode 200, that is, such that the first conductive semiconductor layer or the second conductive semiconductor layer are in contact with both ends. In addition, when an electrode layer (not illustrated) or a polarization inducing layer (not illustrated) is further included on the second conductive semiconductor layer 4, the micro-nano LED device 100 may be disposed such that it is arranged to contact the upper surface of the lower electrode 200, or the first conductive semiconductor layer 2 is arranged to contact the upper surface of the lower electrode 200 and the electrode layer is in contact with the upper electrode 300. Meanwhile, in the case of the micro-nano LED device 100 further including a polarization inducing layer (not illustrated), the polarization inducing layer may be disposed on the upper surface of the lower electrode 200.

According to an exemplary embodiment of the present invention, in order to reduce the contact resistance between the micro-nano LED devices 100 disposed on the lower electrode 200 as illustrated in FIG. 2, it may further include a conductive metal layer 500 connecting the conductive semiconductor layer of the micro-nano LED device 100 in contact with the lower electrode 200 and the lower electrode 200. This current-conducting metal layer 500 may be a conductive metal layer, such as silver, aluminum or gold, and it may be formed to have a thickness of about 10 nm, for example.

In addition, it may further include an insulating layer 600 in the space between the micro-nano LED device 100 magnetically aligned on the lower electrode 200 and the upper electrode 300 in electrical contact with the upper portion thereof. This insulating layer 600 prevents electrical contact between the two vertically opposing electrodes 200, 300 and performs a function of making the upper electrode 300 easier to implement.

In the present display 1000, the micro-nano LED devices 100 provided per subpixel may emit substantially the same light color (hereinafter, referred to as a “first example”). In this case, substantially the same light color does not mean that the wavelength of the emitted light is completely the same, but generally refers to light belonging to a wavelength range that can be called the same light color. For example, when the light color is blue, all micro-nano LED devices that emit light in the wavelength range of 420 nm to 470 nm may be considered to emit substantially the same light color. The light color emitted by the micro-nano LED device provided in the display according to the first example of the present invention may be, for example, blue, white or UV.

In the case of this first example, it may further include a separate color conversion layer (not illustrated) included on the upper electrode 300. That is, it may further include a color conversion layer patterned on the upper electrode 300 such that each of a plurality of subpixel spaces independently expresses one color among blue, green and red.

For example, on the upper electrode 300, it may include a patterned color conversion layer in which a blue color conversion layer, a green color conversion layer and a red color conversion layer are patterned such that each of a plurality of subpixel spaces independently expresses any one color among blue, green and red. In this case, considering the wavelength of light emitted by the provided micro-nano LED device 100, the blue color conversion layer, the green color conversion layer and the red color conversion layer may be known color conversion layers that convert the light passing through the color conversion layers into blue, green and red, but the present invention is not particularly limited thereto. Meanwhile, when the micro-nano LED device 100 is a device that emits blue light, a blue color conversion layer is not necessary, and thus, the color conversion layers may include a green color conversion layer and a red color conversion layer.

Additionally, a protective layer (not illustrated) may be further provided to protect the color conversion layers described above. In this case, the protective layer may be a protective layer used in a typical display equipped with color conversion, but the present invention is not particularly limited thereto.

Meanwhile, in the present display 1000, the micro-nano LED devices 100 provided per subpixel may be devices that each independently emit blue, green and red light (hereinafter referred to as a “second example”). For example, at least two devices that are capable of each independently emitting any one color of blue, green and red may be disposed in each of the subpixel spaces S1, S2. Additionally, since the devices themselves disposed in the subpixel spaces S1, S2 emit the desired blue, green or red color, a separate color conversion layer on the upper electrode 300 is not necessary. Meanwhile, a full-color LED display 1000 according to the second example also includes a conductive metal layer 500 to reduce the resistance of the contact portion between the lower electrode 211 and the micro-nano LED devices 100, and an insulating layer 600 that fills the space between the lower electrode 211 and the upper electrode 300, respectively.

Meanwhile, the electrode arrangement such as data electrodes and gate electrodes provided in a typical display is not illustrated in FIG. 1, and the electrode arrangement that is not illustrated may be an electrode arrangement used in a typical display. Spaces (sub-pixel sites) where subpixels are formed, which are determined according to the electrode arrangement of the display, may be formed on the lower electrode. For example, FIG. 1 illustrates that subpixel spaces S1, S2 are formed in a certain area on two adjacent electrodes, but the present invention is not limited thereto.

Additionally, the subpixel space may have a unit area of 100 μm×100 μm or less, in another example, 30 μm×30 μm or less, and in another example, 20 μm×20 μm or less. Since the unit area of this size is smaller than the unit subpixel area of a display using LED, it is possible to achieve a larger area while minimizing the area ratio occupied by the LED. Accordingly, it may be advantageous to implement a high-resolution display. Meanwhile, the unit area of each subpixel space may be different from each other. Additionally, separate surface treatment may be performed on the surface of the subpixel spaces, or grooves may be formed.

At least two micro-nano LED devices 100 arranged in this subpixel space is a device whose device length is greater than the thickness and in which a first conductive semiconductor layer 2, a photoactive layer 3 and a second conductive semiconductor layer 4 are stacked in the thickness direction. More specifically, referring to FIG. 5, in the micro-nano LED device 100, based on the mutually perpendicular X, Y and Z axes, the X-axis direction may be referred to as length, the Y-axis direction may be referred to as width, and the Z-axis direction may be referred to as thickness, respectively. In this case, the micro-nano LED device 100 is a rod-shaped device with a predetermined shape in the X-Y plane consisting of length and width. In this case, the direction perpendicular to the plane becomes the thickness direction, the length of the device becomes the long axis, and the thickness becomes the short axis.

This micro-nano LED device 100 may be a device in which a first conductive semiconductor layer 2, a photoactive layer 3 and a second conductive semiconductor layer 4 are each sequentially stacked in the thickness direction. The micro-nano LED device 100 of this structure has the advantage of securing a larger light-emitting area due to the plane consisting of length and width even if the thickness of a photoactive layer 3 in the portion exposed on the side is thinned. As a result, the light-emitting area of the micro-nano LED device 100 may have a large light-emitting area that exceeds twice the area of the longitudinal cross-section of the micro-nano LED device. Herein, the longitudinal cross-section is a cross-section parallel to the X-axis direction, which is the longitudinal direction, and may be the X-Y plane in the case of a device with a constant width.

Specifically, the description will be provided by comparing FIGS. 5 and 6. Both of the micro-nano LED device 100 illustrated in FIG. 5 and the horizontally arranged rod-type LED device 100′ illustrated in FIG. 6 have a structure in which a first conductive semiconductor layer 2, a photoactive layer 3 and a second conductive semiconductor layer 4 are stacked. In this case, the micro-nano LED device 100 and the horizontally arranged rod-type LED device 100′ may be rod-type LED devices having the same length (1) and thickness (m) and the same thickness (h) of the photoactive layer. However, in the micro-nano LED device 100, the first conductive semiconductor layer 2, the photoactive layer 3 and the second conductive semiconductor layer 4 are stacked in the vertical thickness direction. On the other hand, the horizontally arranged rod-type LED device 100′ has structural differences from the micro-nano LED device 100 because each layer is stacked in the horizontal longitudinal direction.

In particular, the two devices 100, 100′ have a large difference in light-emitting area. For example, the length (l) may be assumed to be 4500 nm, the thickness (m) may be assumed to be 600 nm, and the thickness (h) of the photoactive layer 3 may be assumed to be 100 nm, respectively. In this case, the ratio of the surface area of the photoactive layer 3 of the micro-nano LED device 100 corresponding to the light-emitting area to the surface area of the photoactive layer 3 of the horizontally arranged rod-type LED device 100′ is 6.42 μm²: 0.75 μm². Accordingly, the light-emitting area of the micro-nano LED device 100 is 8.56 times larger than the light emitting area of the rod-type LED device 100′. In addition, the ratio of the surface area of the externally exposed photoactive layer 3 to the light-emitting area of the entire photoactive layer is similar for the micro-nano LED device 100 and the horizontally arranged rod-type LED device 100′. However, since the absolute value of the unexposed surface area of the photoactive layer 3 is much larger, the influence of the exposed surface area on exciton is much reduced, and thus, the influence of surface defects on exciton becomes much smaller in the micro-nano LED device 100 than in the horizontally arranged rod-type LED device 100′. As a result, in terms of the light-emitting efficiency and brightness, it can be evaluated that the micro-nano LED device 100 is significantly superior to the horizontally arranged rod-type LED device 100′.

Moreover, in the case of the horizontally arranged rod-type LED device 100′, it is implemented by etching a wafer in the thickness direction, in which a conductive semiconductor layer and a photoactive layer are stacked in the thickness direction. Accordingly, the long device length corresponds to the wafer thickness, and in order to increase the length of the device, an increase in the etching depth is inevitable. However, as the etching depth increases, the possibility of defects occurring on the device surface increases, and eventually, even though the area of the exposed photoactive layer of the horizontally arranged rod-type LED device 100′ is smaller than that of the micro-nano LED device 100, the possibility of surface defects occurring is greater. Accordingly, when considering a decrease in the light-emitting efficiency due to the increased possibility of surface defects, the micro-nano LED device 100 may be significantly superior to the horizontally arranged rod-type LED device 100′ in terms of the light-emitting efficiency and brightness.

Furthermore, the movement distances of the holes injected from any one of the first conductive semiconductor layer 2 and the second conductive semiconductor layer 4 and the electrons injected from the other one are short for the micro-nano LED device 100 compared to the horizontally arranged rod-type LED device 100′. As a result, the micro-nano LED device 100 has a reduced probability of electrons and/or holes being captured due to defects in the wall during electron and/or hole movement, thereby minimizing light emission loss, and it may also be advantageous to minimize light emission loss due to electron-hole speed imbalance. Additionally, in the case of the horizontally arranged rod-type LED device 100′, a strong optical path behavior occurs due to the circular rod-shaped structure, and thus, the path of light generated by electrons and holes resonates in the longitudinal direction. Accordingly, since the horizontally arranged rod-type LED device 100′ emits light from both ends in the longitudinal direction, when the device is arranged lying down, the front light emission efficiency is poor due to a strong side light emission profile. On the other hand, in the case of the micro-nano LED device 100, since it emits light from the upper and lower surfaces, it has the advantage of achieving excellent front light-emitting efficiency and thereby improving the front brightness of the display.

In the micro-nano LED device 100 included in an exemplary embodiment of the present invention, the plane is illustrated as a rectangle in FIG. 5, but the present invention is not limited thereto. That is, the micro-nano LED device 100 may be formed in various shapes without limitation, ranging from a general square shape such as a rhombus, parallelogram or trapezoid to a circular or oval shape.

In addition, the micro-nano LED device 100 according to an exemplary embodiment of the present invention has a length and width of micro- or nano-units. For example, in the micro-nano LED device 100, the length may be 1,000 nm to 10,000 nm, the width may be 100 nm to 3,000 nm, and the thickness may be 100 nm to 3,000 nm. The standards for length and width may vary depending on the shape of the plane. For example, if the plane is a rhombus or parallelogram, one of the two diagonals may be the length, and the other one may be the width. Alternatively, in the case of a trapezoid, the longer of the height, top side and bottom side may be the length, and the shorter side perpendicular to the long side may be the width. Alternatively, when the shape of the plane is an ellipse, the major axis of the ellipse may be the length, and the minor axis may be the width.

The length-to-thickness ratio of the micro-nano LED device 100 may be greater than 3:1, and more preferably, greater than 6:1. Through this, it has the advantage of enabling easier magnetic alignment to the electrode through an electric field. If the length-to-thickness ratio of the micro-nano LED device 100 is reduced to less than 3:1, it may be difficult to magnetically align the device on the electrode through an electric field, and the device may not be fixed on the electrode, and thus, there is a risk of electrical contact short-circuiting caused by a process defect. However, the length-to-thickness ratio may be 15:1 or less, which may be advantageous for achieving the aspects of the present invention, such as optimizing the turning force that causes magnetic alignment through an electric field.

In addition, the ratio of the length and width in the plane may also be larger, preferably, 3:1 or more, and more preferably, 6:1 or more, and through this, it has the advantage of enabling easier magnetic alignment to the electrode through an electric field. However, the ratio of the length and width may be less than 15:1, and through this, it may be advantageous for optimizing the turning force of magnetic alignment through an electric field when performing the alignment function. In this case, the turning force refers to a force (e.g., magnetic force) that generates movement (i.e., turning movement) in the micro-nano LED device 100 that was arranged in the reverse direction through the electric field generated by the voltage applied to the electrodes 211, 212, thereby aligning the fin LED device 100 in the forward direction again.

Additionally, the width of the micro-nano LED device 100 may be greater than or equal to the thickness. Through this, when the micro-nano LED device 100 is aligned on the two electrodes 211, 212 of the lower electrode 200 using an electric field during the manufacturing process of the display 1000, it has the advantage of minimizing or preventing the alignment while lying on its side. When the micro-nano LED device is aligned lying on its side, even if alignment and mounting are achieved with one end and the other end in contact with two different electrodes, respectively, the device may not emit light due to an electrical short circuit that occurs as the photoactive layer exposed on the side of the device contacts the electrode. As a result, display brightness may be reduced or defective pixels may be generated.

Additionally, the micro-nano LED device 100 may be a device with different sizes at both ends in the longitudinal direction. For example, it may be a rod-type LED device having a rectangular plane that is an equilateral trapezoid whose length and height are greater than the top and bottom sides. Additionally, depending on the difference in length between the top and bottom sides, a difference between positive and negative charges accumulated at both ends of the device in the longitudinal direction may be generated. Through this, there is an advantage that magnetic alignment can be made easier by an electric field.

In addition, unlike as illustrated in FIG. 5, the lower surface of the first conductive semiconductor layer 2 of the micro-nano LED device 100 may be formed with a protrusion (not illustrated) having a predetermined width and thickness in the longitudinal direction of the device. For example, such a protrusion may be created as a result of etching the wafer in the thickness direction and then etching the etched LED portion horizontally inward from both side surfaces of the bottom of the etched LED portion to remove the same from the wafer. The protrusion may help perform improvements to front light extraction of the micro-nano LED device 100. In addition, when the micro-nano LED device 100 is magnetically aligned on the lower electrode 200, the protrusion may help control the alignment such that the opposite surface (e.g., the exposed surface of the second conductive semiconductor layer) opposite to one surface of the device on which the protrusion is formed is located on the lower electrode 200. Meanwhile, after the opposite surface is located on the lower electrode 200, the upper electrode 300 may be formed on the upper surface where the protrusion of the micro-nano LED device 100 is formed. In this case, the protrusion increases the contact area with the formed upper electrode 300, and thus, the mechanical bonding force between the upper electrode 300 and the micro-nano LED device 100 may be improved.

The width of the protrusion may be formed to be 50% or less of the width of the micro-nano LED device 100, and more preferably, 30% or less. Through this, it may be easier to separate the micro-nano LED device portion etched on the LED wafer. If a protrusion is formed by exceeding 50% of the width of the micro-nano LED device 100, the separation of the micro-nano LED device portion etched on the LED wafer may not be easy, separation may occur in a non-targeted area, thereby reducing mass productivity, and there is a risk that the uniformity of the micro-nano LED device produced in a plurality may deteriorate. Meanwhile, the width of the protrusion may be formed to be 10% or more of the width of the micro-nano LED device 100. If the width of the protrusion is formed to be less than 10% of the width of the micro-nano LED device 100, separation may be easy on the LED wafer. However, in this case, there is a risk that a portion of the first conductive semiconductor layer 2 that must not be etched may be etched due to excessive etching during side etching, and the effect of the protrusion described above may not be achieved. In addition, there is a risk of separation by the wet etching solution, and there may be a problem in that the micro-nano LED devices dispersed in the high-risk etching solution having strong basic properties must be separated from the wet etching solution and cleaned.

In addition, the thickness of the protrusion may be 10 to 30% of the thickness of the first conductive semiconductor layer 2. Through this, the first conductive semiconductor layer 2 may be formed with the desired thickness and quality, and it may be more advantageous to generate the effect through the above-mentioned protrusion. Herein, the thickness of the first conductive semiconductor layer 2 refers to a thickness based on the lower surface of the first conductive semiconductor layer 2 on which no protrusions are formed. For example, the width of the protrusion may be 50 to 300 nm, and the thickness may be 50 to 400 nm.

Next, the driving method according to an exemplary embodiment of the present invention will be described.

FIG. 7 shows a flowchart of the driving method according to an exemplary embodiment of the present invention.

The driving method according to an exemplary embodiment of the present invention is a driving method for the present display 1000, which may include a step of switching the driving function and an alignment function for the micro-nano LED elements 100 depending on the on/off of the switch 700.

Specifically, the present driving method includes S101 and S102, as illustrated in FIG. 7. However, the present driving method may perform only S102, or perform S101 and S102, and in this case, S101 and S102 are not sequential, and the execution order may be changed. In addition, S101 and S102 may be performed alternately or may be performed repeatedly.

S101 is a step in which the alignment function is performed (i.e., alignment step), and S102 is a step in which the driving function is performed (i.e., driving step). In this case, the switch 700 may be turned off in S101, and the switch 700 may be turned on in S102. Additionally, in S101, a high voltage may be applied to the first electrode 211, and a low voltage may be applied to the second electrode 212 among the adjacent electrodes 211, 212 of the lower electrode 200. Additionally, in S101, a low voltage may be alternately applied to the adjacent electrodes 211, 212 of the lower electrode 200. Additionally, in S102, a high voltage may be applied to the upper electrode 300, and a low voltage may be applied to the lower electrode 200.

S101 may correspond to an optional step in the present driving method. For example, S101 may be performed during the manufacturing process of the present display 1000, but the present invention is not limited thereto. According to the present driving method, while the driving function is being performed according to S102 after the manufacturing process of the display 1000, it may be additionally performed if necessary.

However, since the alignment and driving functions related to S101 and S102 are the same as described above with reference to FIGS. 3 and 4, the detailed descriptions thereof will be omitted below.

The present invention configured as described above has the advantage of providing an electrode structure technique that can be used for aligning and driving the corresponding LED devices in the pixel structure of a display using ultra-thin fin LED devices. That is, the present invention has the advantage of efficiently performing alignment and driving functions, by implementing a switching function that can switch functions to alignment and driving electrodes in the pixel structure of a display using ultra-thin fin LED devices. In addition, the present invention has the advantage of significantly improving the lifespan of the ultra-thin fin LED device affected by the voltage of the adjacent electrodes by applying a low voltage alternately to the first electrode 211 and the second electrode among the adjacent electrodes of the lower electrode when performing the driving function. In addition, the present invention has the advantage of contributing to improving image quality while implementing reflection and shielding functions at low cost through the lower electrode.

In the detailed description of the present invention, specific exemplary embodiments have been described, but certainly, various modifications are possible without departing from the scope of the present invention. Therefore, the scope of the present invention is not limited to the described exemplary embodiments, but should be defined by the claims described below and equivalents to these claims.

What is claimed is:

1. A display, comprising:
a lower electrode comprising a plurality of electrodes that are spaced apart in the horizontal direction at a predetermined interval;
ultra-thin fin LED devices as devices in which the length is greater than the thickness and a first conductive semiconductor layer, a photoactive layer and a second conductive semiconductor layer are stacked in the thickness direction, and at least two thereof are provided for each of a plurality of sub-pixel sites formed on the lower electrode;
an upper electrode disposed to contact the top of the ultra-thin fin LED devices; and
a switch with one end connected to the first electrode and the other end connected to the second electrode for the first and second electrodes that are adjacent to the lower electrode in each subpixel space,
wherein in the on state of the switch, a driving function for the ultra-thin fin LED devices is performed.

2. The display of claim 1, wherein the driving function and an alignment function for the ultra-thin fin LED devices are switched depending on the on/off of the switch, and
wherein when the alignment function is performed, the switch is turned off.

3. The display of claim 1, wherein an alignment function for the ultra-thin fin LED devices is performed in the off state of the switch, and the alignment function is performed during a manufacturing process.

4. The display of claim 2, wherein during the alignment function, a high voltage is applied to the first electrode and a low voltage is applied to the second electrode.

5. The display of claim 1, wherein during the driving function, a high voltage is applied to the upper electrode and a low voltage is applied to the lower electrode.

6. The display of claim 1, wherein during the driving function, a low voltage is alternately applied to the first and second electrodes.

7. The display of claim 1, wherein the lower electrode is provided in the form of a plate and comprises a reflective material on a surface that reflects the light emitted from the ultra-thin fin LED devices in each subpixel space to an upper portion which is the front surface.

8. The display of claim 1, wherein the lower electrode comprises a shielding material that blocks an electric field induced from a transistor and a signal line that are disposed on the lower side in each subpixel space.

9. The display of claim 1, wherein the lower electrode is provided in the form of a plate, comprises a reflective material on a surface that reflects the light emitted from the ultra-thin fin LED devices in each subpixel space to an upper portion, which is the front surface, and comprises a shielding material that blocks an electric field induced from a transistor and a signal line that are disposed on the lower side.

10. The display of claim 7, wherein each thickness of the first and second electrodes in the horizontal direction is greater than a separation interval in the horizontal direction between the first and second electrodes.

11. The display of claim 7, wherein a separation interval in the horizontal direction between the second electrode located in the first subpixel space and a third electrode located in the second subpixel space but adjacent to the second electrode is smaller than each thickness in the horizontal direction of the first and second electrodes.

12. A method for driving a display, the display comprising:
a lower electrode comprising a plurality of electrodes that are spaced apart in the horizontal direction at a predetermined interval; ultra-thin fin LED devices as devices in which the length is greater than the thickness and a first conductive semiconductor layer, a photoactive layer and a second conductive semiconductor layer are stacked in the thickness direction, and at least two thereof are provided for each of a plurality of sub-pixel sites formed on the lower electrode; an upper electrode disposed to contact the top of the ultra-thin fin LED devices; and a switch with one end connected to the first electrode and the other end connected to the second electrode for the first and second electrodes that are adjacent to the lower electrode in each subpixel space, respectively,
wherein the method comprises a driving step of performing the driving function when the switch is turned on.

13. The method of claim 11, further comprising the step of:
switching the driving function and an alignment function for the ultra-thin fin LED devices according to the on/off of the switch,
wherein when the alignment function is performed, the switch is turned off.

14. The method of claim 12, wherein during the alignment function, a high voltage is applied to the first electrode and a low voltage is applied to the second electrode.

15. The method of claim 12, wherein the driving step comprises the step of applying a high voltage to the upper electrode and applying a low voltage to the lower electrode.

16. The method of claim 12, wherein the driving step comprises the step of applying a low voltage alternately to the first and second electrodes.
